(19) United States
(12) Patent Application Publication
(10) Pub. No.: US 2005/0195580 A1
(43) Pub. Date: Sep. 8, 2005

(54) Electronic card

(76) Inventor: Frank Lin, Taipei Hsien (TW)

Correspondence Address: NIKOLAI & MERSEREAU, P.A., 900 SECOND AVENUE SOUTH, SUITE 820, MINNEAPOLIS, MN, 55402, US

(21) Appl. No.: 10/796,517

(22) Filed: Mar. 8, 2004

(51) Int. Cl. H05K 5/00

(52) U.S. Cl. 361/752; 361/759

(57) ABSTRACT

An electronic card includes two shells juxtaposed to each other, and a frame mounted between the two shells. The frame has two sides each formed with a locking groove, and each of the two shells has two sides each formed with a locking hook detachably locked in the respective locking groove of the frame. Thus, the electronic card is manufactured easily, thereby greatly decreasing costs of fabrication of the electronic card. In addition, the user only needs to remove one of the two shells from the frame to expose the circuit board, thereby facilitating maintenance of the circuit board.

### BACKGROUND OF THE INVENTION

1. Field of the Invention

The present invention relates to an electronic card, and more particularly to an electronic card that is manufactured easily, thereby greatly decreasing costs of fabrication of the electronic card.

2. Description of the Related Art

A conventional electronic card, such as a memory card, network card or the like is used to store data or used for network transmission. The electronic card is usually portable and has an externally connection function, thereby facilitating a user carrying and using the electronic card. However, each of the parts of the electronic card has an asymmetric structure, so that the electronic card is not made easily, thereby increasing costs of fabrication of the electronic card. In addition, the parts of the conventional electronic card are not assembled easily and conveniently. Further, the parts of the conventional electronic card are not combined rigidly and stably, so that the conventional electronic card easily becomes loosened or detached due to an external force during a long-term utilization.

### SUMMARY OF THE INVENTION

The primary objective of the present invention is to provide an electronic card that is manufactured easily, thereby greatly decreasing costs of fabrication of the electronic card.

Another objective of the present invention is to provide an electronic card, wherein the parts of the electronic card are assembled easily and conveniently, thereby facilitating a user mounting the electronic card.

A further objective of the present invention is to provide an electronic card, wherein the user only needs to remove one of the two shells from the frame to expose the circuit board, thereby facilitating maintenance of the circuit board.

A further objective of the present invention is to provide an electronic card, wherein each of the two shells is combined with the frame rigidly and stably, thereby greatly enhancing the structural strength of the electronic card.

In accordance with the present invention, there is provided an electronic card, comprising two shells juxtaposed to each other, and a frame mounted between the two shells, wherein:
the frame has two sides each formed with a locking groove, and each of the two shells has two sides each formed with a locking hook detachably locked in the respective locking groove of the frame.

Further benefits and advantages of the present invention will become apparent after a careful reading of the detailed description with appropriate reference to the accompanying drawings.

### BRIEF DESCRIPTION OF THE DRAWINGS

FIG. 1 is a perspective view of an electronic card in accordance with the preferred embodiment of the present invention;

FIG. 2 is an exploded perspective view of the electronic card as shown in FIG. 1;

FIG. 3 is an exploded perspective view of the electronic card as shown in FIG. 1; and

FIG. 4 is a partially cut-away perspective enlarged view of the electronic card as shown in FIG. 1.

### DETAILED DESCRIPTION OF THE INVENTION

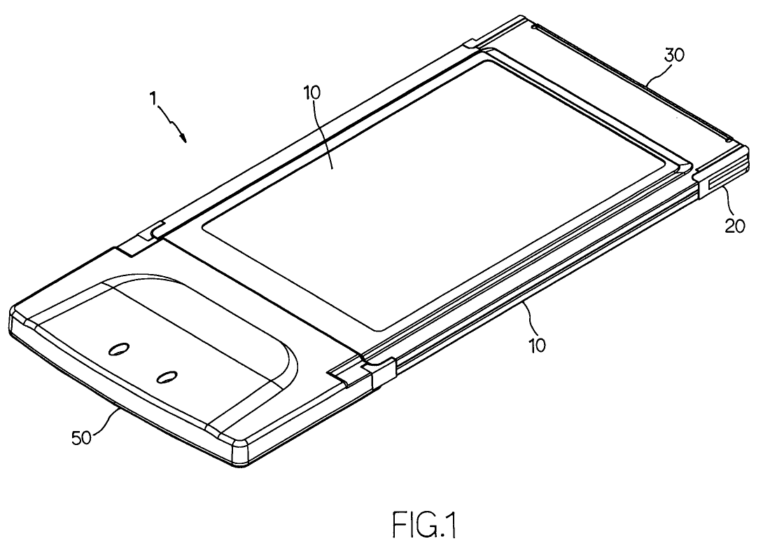

Referring to the drawings and initially to FIG. 1, an electronic card 1 in accordance with the preferred embodiment of the present invention comprises two symmetric shells 10 juxtaposed to each other, a frame 20 mounted between the two shells 10, a circuit board 40 mounted between the two shells 10 and rested on the frame 20, a terminal seat 30 mounted on a first end of the frame 20 and secured on a first end of the circuit board 40, and an extension 50 mounted on a second end of the frame 20 and rested on a second end of the circuit board 40.

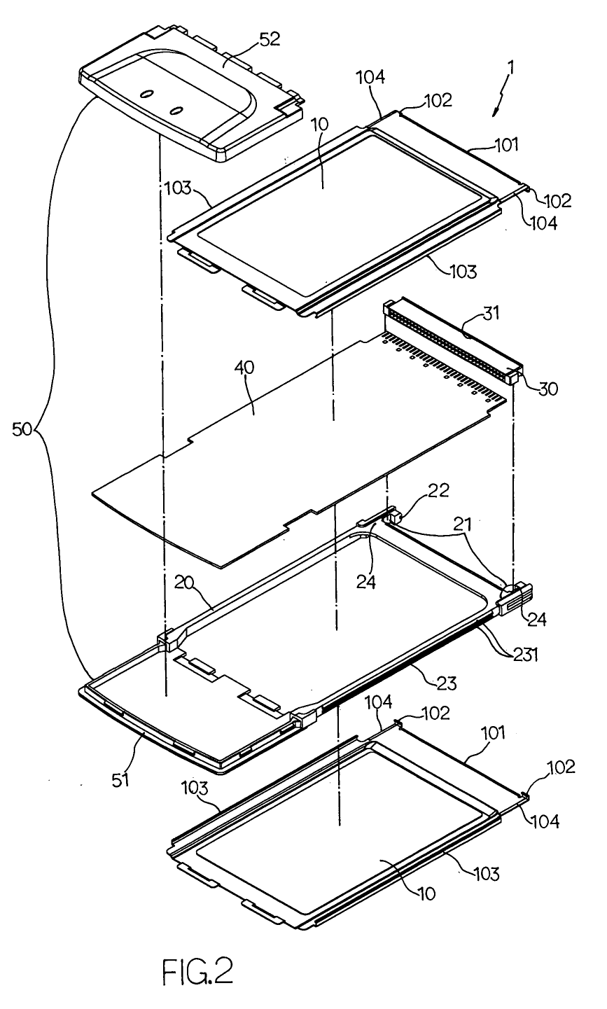

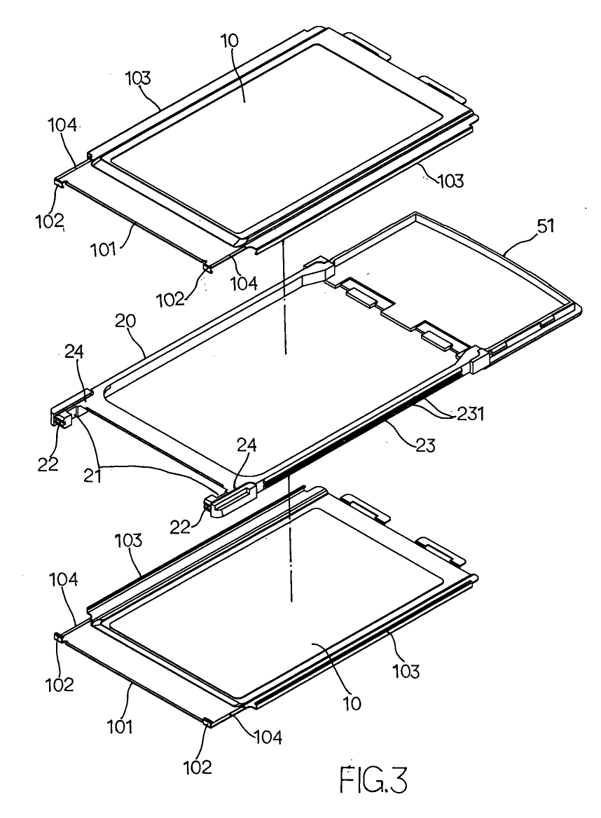

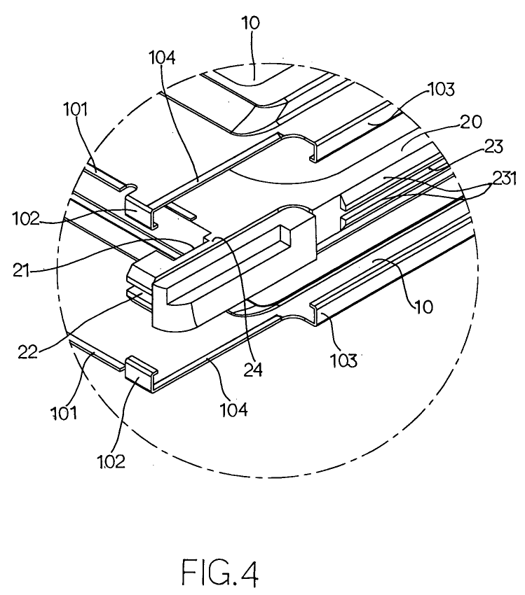

Referring to FIGS. 1-4, each of the two shells 10 has a first end formed with a bent edge 101 rested on the terminal seat 30.

The terminal seat 30 has two sides each formed with an oblique insertion channel 31, and the bent edge 101 of each of the two shells 10 is inserted into the respective insertion channel 31 of the terminal seat 30, so that each of the two shells 10 is closely combined with the terminal seat 30, thereby preventing the terminal seat 30 from becoming loosened or detached from the two shells 10 due to an external force during a long-term utilization.

The first end of the frame 20 is formed with an insertion recess 21, and the terminal seat 30 is inserted into the insertion recess 21 of the frame 20.

The first end of the frame 20 has two sides each formed with a positioning recess 22, and the first end of each of the two shells 10 has two sides each formed with a substantially L-shaped bent positioning hook 102 detachably locked in the respective positioning recess 22 of the frame 20, so that the first end of each of the two shells 10 is detachably mounted on the first end of the frame 20.

The frame 20 has two sides each formed with a locking groove 23, and each of the two shells 10 has two sides each formed with a substantially L-shaped bent locking hook 103 detachably locked in the respective locking groove 23 of the frame 20, so that each of the two shells 10 is detachably mounted on the frame 20. Preferably, the locking groove 23 of each of the two sides of the frame 20 is formed with two spaced elongated catch ribs 231 for retaining the respective locking hook 103 of each of the two shells 10.

Each of the two sides of the first end of each of the two shells 10 is formed with an inclined edge 104 located adjacent to the positioning hook 102, and each of the two sides of the first end of the frame 20 is formed with two press faces 24 each urged on the respective inclined edge 104 of each of the two shells 10, so that each of the two shells 10 is combined with the frame 20 rigidly and stably.

The extension 50 includes a first casing 51 mounted on the second end of the frame 20 and a second casing 52 removably mounted on the first casing 51, so that the circuit board 40 or an antenna for network transmission is received in the extension 50 between the first casing 51 and the second casing 52. In practice, when the electronic card 1 is used in the network transmission, the extension 50 provides a receiving space for mounting the antenna circuit. Alternatively, when the electronic card 1 is used in the memory, the extension 50 provides a receiving space for extension of the circuit board 40.

Accordingly, each of the two shells 10 has a symmetric structure, so that the two shells 10 are manufactured easily, thereby decreasing costs of fabrication of the electronic card 1. In addition, the parts of the electronic card 1 are assembled easily and conveniently, thereby facilitating a user mounting the electronic card 1. Further, the user only needs to remove one of the two shells 10 from the frame 20 to expose the circuit board 40, thereby facilitating maintenance of the circuit board 40. Further, each of the two shells 10 is combined with the frame 20 rigidly and stably, thereby greatly enhancing the structural strength of the electronic card 1.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. An electronic card, comprising two shells juxtaposed to each other, and a frame mounted between the two shells, wherein:
the frame has two sides each formed with a locking groove, and each of the two shells has two sides each formed with a locking hook detachably locked in the respective locking groove of the frame.

2. The electronic card in accordance with claim 1, further comprising a terminal seat mounted on a first end of the frame, wherein each of the two shells has a first end formed with a bent edge rested on the terminal seat.

3. The electronic card in accordance with claim 2, wherein the terminal seat has two sides each formed with an oblique insertion channel, and the bent edge of each of the two shells is inserted into the respective insertion channel of the terminal seat.

4. The electronic card in accordance with claim 1, wherein the frame has a first end having two sides each formed with a positioning recess, and each of the two shells has a first end having two sides each formed with a positioning hook detachably locked in the respective positioning recess of the frame.

5. The electronic card in accordance with claim 4, wherein the positioning hook of each of the two shells is substantially L-shaped.

6. The electronic card in accordance with claim 4, wherein each of the two sides of the first end of each of the two shells is formed with an inclined edge located adjacent to the positioning hook, and each of the two sides of the first end of the frame is formed with two press faces each urged on the respective inclined edge of each of the two shells.

7. The electronic card in accordance with claim 1, further comprising a circuit board mounted between the two shells and rested on the frame, and a terminal seat mounted on a first end of the frame and secured on a first end of the circuit board.

8. The electronic card in accordance with claim 7, wherein the first end of the frame is formed with an insertion recess, and the terminal seat is inserted into the insertion recess of the frame.

9. The electronic card in accordance with claim 1, wherein the locking hook of each of the two shells is substantially L-shaped.

10. The electronic card in accordance with claim 1, wherein the locking groove of each of the two sides of the frame is formed with two spaced elongated catch ribs for retaining the respective locking hook of each of the two shells.

11. The electronic card in accordance with claim 1, wherein each of the two shells has a symmetric structure.

12. The electronic card in accordance with claim 7, further comprising an extension mounted on a second end of the frame and rested on a second end of the circuit board.

13. The electronic card in accordance with claim 12, wherein the extension includes a first casing mounted on the second end of the frame and a second casing removably mounted on the first casing, so that the circuit board is received in the extension between the first casing and the second casing.
